(19) United States
(12) Patent Application Publication
(10) Pub. No.: US 2026/0245835 A1
(43) Pub. Date: Aug. 20, 2026

(54) INTEGRATED SUBSTRATE PROCESSING APPARATUS AND METHOD

(71) Applicant: Picosun Oy, Espoo (FI)

(72) Inventors: Jani HÄMÄLÄINEN, Espoo (FI); Thomas KNISLEY, Detroit, MI (US); Tom BLOMBERG, Espoo (FI); Fabien PIALLAT, Bernin (FR); Safdar MUHAMMAD, Espoo (FI); Soumen MAZUMDER, Espoo (FI)

(21) Appl. No.: 19/053,484

(22) Filed: Feb. 14, 2025

(51) Int. Cl. H01J 37/32; C23C 16/40; C23C 16/455; C23C 16/50; H01L 21/02; H01L 21/285

(52) U.S. Cl. CPC H01J 37/32357; C23C 16/402; C23C 16/45544; C23C 16/50; H01J 37/32899; H10P 14/43; H10P 14/6336; H10P 14/6339; H10P 14/6504; H01J 2237/332; H01J 2237/335

(57) ABSTRACT

An integrated substrate processing apparatus (100) comprises substrate modules integrated, under vacuum, via a wafer handling module (150). The substrate modules comprise a first substrate processing module (110) provided with a remote plasma generator (115), configured to process one substrate (101) at a time in a plasma-enhanced process, and a second substrate processing module (120) capable of processing at least one batch of substrates (101) in a thermal mode for thin film deposition, said second substrate processing module (120) comprising a heated substrate support (215).

### FIELD

The present invention generally relates to integrated substrate processing apparatuses capable of chemical deposition of material on substrate surface(s).

### BACKGROUND

This section illustrates useful background information without admission of any technique described herein representative of the state of the art.

Atomic layer deposition, ALD, is a special chemical deposition method that is based on sequential introduction of at least two reactive precursor species to at least one substrate. ALD is known to produce highly uniform conformal coatings on a substrate surface. Conventionally, ALD thin films have been deposited in a single reactor. However, currently more interest has been shown towards integrated substrate processing apparatuses, comprising more than one reaction chamber module. When there is more than one reaction chamber module, certain problems not present in single chamber reactors will become relevant for integrated substrate processing apparatuses. These often involve the overall optimization of substrate processing, such as performing pre-processing and subsequent processing or substrate transfer within the apparatuses.

### SUMMARY

It is an object of certain embodiments of the invention to optimize substrate processing in an integrated substrate processing apparatus or at least to provide an alternative solution to existing technology.

According to a first example aspect of the invention there is provided an integrated substrate processing apparatus, comprising substrate modules integrated, under vacuum, via a wafer handling module, wherein the substrate modules comprise: a first substrate processing module provided with a remote plasma generator, configured to process one substrate at a time in a plasma-enhanced process, and a second substrate processing module capable of processing at least one substrate at a time in a thermal mode for thin film deposition, said second substrate processing module comprising a heated substrate support. Advantageously, the heated substrate support will bring the substrate to a temperature to promote an even growth rate and hence improve uniformity in thin film deposition.

In certain embodiments, the first substrate processing module is a processing module of a single substrate (in contrast to a batch processing module). In certain embodiments, the second substrate processing module is a processing module of a single substrate. In certain embodiments, both the first and the second substrate processing modules are processing modules of a single substrate. Herein, a processing module of a single substrate is understood to be a substrate processing module having room for a single substrate only (in a reaction chamber of the respective module). In certain embodiments, instead of a processing module of a single substrate, the second substrate processing module is a batch processing module.

In certain embodiments, the processing within the first substrate processing module occurs prior to the processing within the second substrate processing module. Accordingly, the processing within the second substrate processing module is subsequent to the processing within the first substrate processing module.

In certain embodiments, the plasma-enhanced process is a self-limiting process, such as a process based on self-limiting surface reactions. In certain embodiments, the plasma-enhanced process is a deposition process (thin film process). In certain embodiments, the plasma-enhanced process is a removal process (e.g. for substrate surface cleaning), such as an etching process, for removal of one or more materials, compounds or elements. In certain embodiments, the plasma-enhanced process is a modification process. In certain embodiments, the modification process is a cleaning, doping, altering or smoothing process. In certain embodiments, the substrate(s) is/are wafer(s). In certain other embodiments, the substrate(s) is/are something else than wafers, for example, 3-dimensional (non-planar) substrate(s), pellicle(s) of carbon nano tubes, mask(s) or similar.

In certain embodiments, a flow of plasma species is generated at a location remote from the substrate (e.g., on the outside of a respective reaction chamber). In certain embodiments, the apparatus (first substrate processing module) comprises an in-feed part to deliver (or guide) a generated flow of plasma species, preferably radicals, from the remote plasma generator to the substrate. In certain embodiments, the generated flow of plasma species is directed from the remote plasma generator to the substrate via an in-feed part, providing a flow channel, formed of one or more parts. In certain embodiments, the in-feed part provides a non-curved flow path from the remote plasma generator to the substrate. In certain embodiments, the said one or more parts comprise tubular part(s). In certain embodiments, the tubular part(s) comprise cylindrical and/or conical part(s). In certain embodiments, the in-feed part comprises a trumpet-shaped part. In certain embodiments, the in-feed part comprises a first conical part followed by a second conical part. In certain embodiments, the in-feed part comprises a cylindrical part followed by a conical part. In certain embodiments, the in-feed part comprises a cylindrical part followed by a trumpet-shaped part. The trumpet-shaped part herein means a conical part flaring at its broad end. In certain embodiments, a centerline of a plasma formation section of the remote plasma generator extends to a center point of a substrate holder (without there being any flow obstacles in between). In certain embodiments, said flow channel is symmetrically arranged with respect to the centerline. In certain embodiments, the remote plasma generator is a microwave remote plasma generator. In certain embodiments, the first substrate processing module comprises an in-feed part to direct a plasma species, preferably radicals, from the remote plasma generator to the substrate without there being any flow obstacles in between the remote plasma generator and the substrate. In certain embodiments, the in-feed part provides a flow path extending from the remote plasma generator to the substrate wherein there is no flow obstacle within the flow path.

In certain embodiments, the first substrate processing module comprises an in-feed part to deliver a generated flow of plasma species from the remote plasma generator to the substrate, wherein the in-feed part comprises a top part, and a bottom part slidable, at least partly, over the top part to form a space for substrate loading.

In certain embodiments, the substrate modules comprise at least one further module selected from a group consisting of: a front-end module, a pre-post processing module such as a buffer module for temporary storing of substrates, a substrate aligner module, a cooling module, and an optional further module.

In certain embodiments, the substrate modules comprise a buffer module. In certain embodiments, the substrate modules comprise a front-end module and a buffer module, and optionally a substrate aligner module. In certain embodiments, the substrate modules comprise a front-end module, a buffer module, and a cooling module, and optionally a substrate aligner module. In certain embodiments, the substrate modules comprise a front-end module, a buffer module, and a substrate aligner module.

In certain embodiments, the integrated substrate processing apparatus is configured to handle substrates as horizontally oriented throughout the apparatus.

In certain embodiments, the integrated substrate processing apparatus comprises an in-feed part, operating as a directing means, to guide plasma generated by the remote plasma generator to the substrate.

In certain embodiments, the first substrate processing module comprises a conical in-feed part for a top-to-bottom flow of plasma species.

Accordingly, in certain embodiments, the flow of plasma species (excited species) is directed towards a substrate surface through a cone as a top-to-bottom flow. The top-to-bottom flow herein refers to a substantially vertical flow passing through a reaction chamber. In certain embodiments, the reaction chamber comprises gas in-feed above the substrate and an exhaust line (or exhaust connection) beneath the substrate.

In certain embodiments, the conical in-feed part comprises a cone.

In certain embodiments, the conical in-feed part (herein referred to as a plasma cone) is a retractable cone.

In certain embodiments, the in-feed part comprises first a cylindrical or conical part followed by a trumpet-shaped part. In certain embodiments, the in-feed part comprises a cylindrical tube, preferably a straight walled tube, followed by a conical part, more preferably a trumpet shaped part. In certain embodiments, the conical or trumpet-shaped part is slidable over the cylindrical tube (for substrate loading).

In certain embodiments, the first substrate processing module is configured to provide gas activated or excited through the remote plasma generator (to form plasma species), and targeted to the single substrate surface for removal of one or more materials, compounds or elements, preparing the substrate for subsequent processing in the integrated substrate processing apparatus.

Herein, said gas refers, in particular, to Ar, NH₃, N₂ or H₂ or the like and any mixtures thereof.

In certain embodiments, said removal of one or more materials, compounds or elements comprises oxidation or deoxidation or deoxygenation, and/or decarbonation, and/or nitridation (such as re-nitridation).

In certain embodiments, said removal of one or more materials, compounds or elements comprises oxygen or oxide removal. In certain embodiments, said removal of one or more materials, compounds or elements comprises oxygen or oxide removal in a GaN surface process. In certain embodiments, said deoxygenation removes active oxygen from the surface of a noble metal film, such as ruthenium (Ru), as this active oxygen is responsible of providing functional sites for Ru precursor ligands to be partly burned, i.e. causing agglomeration of Ru particles and hence limiting the small, high density Ru nuclei to be distributed more evenly, for example in the preparation of carbon nano tubes for EUV (extreme ultraviolet) pellicles. In certain embodiments, said removal of one or more materials, compounds or elements comprises carbon clusters removal. In certain embodiments, said removal of one or more materials, compounds or elements comprises carbon clusters removal in a SiC surface process. In certain embodiments, said removal of one or more materials, compounds or elements comprises oxide removal, oxygen removal, carbon contamination removal and/or re-nitridation of carbon clusters (e.g. in a GaN surface process).

In certain embodiments, the gas reaches the substrate surface via the conical in-feed part (plasma cone).

In certain embodiments, the first substrate processing module comprises a stationary substrate holder. In certain embodiments, the first substrate processing module comprises a heated substrate holder. In certain embodiments, the first substrate processing module comprises a substrate holder integrated with a heating arrangement. In certain embodiments, the stationary substrate holder is a heated substrate holder.

In certain embodiments, the heated substrate support of the second substrate processing module is a stationary substrate support (substrate holder). In certain embodiments, a heating arrangement (or heater element) is integrated into the substrate support of the second substrate processing module (thus implementing the heated substrate support). Accordingly, in certain embodiments, both the substrate holder of the first substrate processing module and the substrate support of the second substrate processing module comprise a respective heater element.

In certain embodiments, the integrated substrate processing apparatus is configured to provide a top-to-bottom flow of a precursor towards the horizontally oriented (positioned) substrate.

Herein, again, the top-to-bottom flow refers to a substantially vertical flow passing through a reaction chamber.

In certain embodiments, the apparatus is configured to load at least one horizontally oriented substrate (e.g. from a buffer chamber) onto a substrate holder within the second substrate processing module.

In certain embodiments, the horizontally oriented substrate is lowered into a reaction chamber and the reaction chamber is closed by a lid. In certain embodiments, the substrate holder is integrated into the lid. In certain embodiments, the lowering of the substrate holder integrated to the lid causes the lid to close the reaction chamber.

In certain embodiments, advantages for remote plasma, preferably microwave-generated remote plasma, include improved thin-film process uniformity and limited plasma damage over the substrate surface. In certain embodiments, advantages for top-to-bottom flow include low particle addition, fast purging and good uniformity.

In certain embodiments, the integrated substrate processing apparatus is configured to deposit one or more thin films selected from the group comprising metals, nitrides, oxides, carbides, and/or laminates thereof, on the surface of one or more substrates.

In certain embodiments, the surface of interest (typically upper surface) of a substrate is prepared within the first substrate processing module by the plasma-enhanced process, and the prepared surface of the substrate is coated by depositing said one of more thin films within the second substrate processing module.

In certain embodiments, the integrated substrate processing apparatus is configured to deposit a thin film on the substrate(s), the thin film selected from the group of metals, non-metal oxides or metal oxides, metal nitrides or metal carbides or alloys thereof. Said metals can be selected from the group comprising metalloids or transition metals, including noble metals, or combinations thereof. In certain embodiments, the metalloid is silicon. In certain embodiments, the transition metal is selected from the group comprising Ti, Zn, Zr, Nb, Hf, Ta, and W and/or combinations of oxides and/or nitrides thereof. In certain embodiments, the noble metal is selected from the group comprising Ru, Pd, Pt, and Ir and/or combinations of oxides thereof. In certain embodiments, the non-metal oxides include SiO₂ and the metal oxides are selected from the group comprising SiO₂, HfO₂, ZrO₂, Al₂O₃, and TiO₂. In certain embodiments, the metal nitrides are selected from the group comprising SiN, AlN, HfN, TiN and AlScN. In certain embodiments, the metal alloy is TiAl(C). In certain embodiments the metals, non-metal oxides, metal oxides, metal nitrides or metal carbides or alloys thereof are deposited as single layers and/or as laminates thereof.

In certain embodiments, the first and/or second processing module comprises at least 4, preferably 4 to 6, independent precursor inlets.

In certain embodiments, the precursor inlets are independent to introduce precursor vapor into a reaction space of the reaction chamber concerned without contamination.

In certain embodiments, the integrated substrate processing apparatus is configured to passivate the substrate(s) in substrate processing modules by depositing a first thin film. In certain embodiments, the integrated substrate processing apparatus is configured to passivate the substrate(s) in substrate processing modules by depositing a second thin film onto a first thin film. In certain embodiments, the first thin film is deposited in the first substrate processing module, and the second thin film, if deposited, in the second substrate processing module. In certain embodiments, the first thin film and the second thin film are deposited in the second substrate processing module.

The first thin film may be thinner than the second thin film. Alternatively the second film may be thinner than the first film.

In certain embodiments, the thickness of the first thin film is in the range extending from 1 to 10 nm and the thickness of the second thin film is in the range extending from 3 to 70 nm.

In certain embodiments, the plasma-enhanced process is a (surface) modification process, and a thin film deposition process is carried out in the second substrate processing module.

In certain embodiments, the integrated substrate processing apparatus comprises substrate modules integrated, under vacuum, via the wafer handling module, wherein vacuum pressure is in the range extending from 100 mPa to 3 kPa.

In certain embodiments, the integrated substrate processing apparatus comprises a processing unit configured to cause the apparatus, under vacuum, to perform for substrate(s):
(a) pre-treatment in the first substrate processing module (plasma tool);
(b) optionally deposition of a film (which may be a passivation layer or a metal or the like) in the first substrate processing module;
[(b2) optionally perform a second pre-treatment in the first substrate processing module (plasma tool);]
(c) optionally transfer to a pre-post processing module via the wafer handling module; and
(d) transfer to the second substrate processing module (thermal tool) [for deposition of a second thin film (which may be a passivation layer or a metal or the like)].

In certain embodiments, there is an option for cooling along each of the stages. In certain embodiments, the pre-treatment comprises substrate surface modification or material removal from substrate surface.

In certain embodiments, the integrated substrate processing apparatus comprises a processing unit configured to cause the apparatus, under vacuum, to perform for substrate(s):
(a) deposition of a film in the first substrate processing module;
(c) optionally transfer to a pre-post processing module via the wafer handling module; and
(d) transfer to the second substrate processing module (thermal tool).

In certain embodiments, the integrated substrate processing apparatus comprises a processing unit configured to cause the apparatus, under vacuum, to perform for substrate(s):
(a) substrate surface modification or material removal process in the first substrate processing module;
(b) optionally transfer to a pre-post processing module via the wafer handling module; and
(c) transfer to the second substrate processing module and deposit a passivation layer (first thin film) and a second thin film (e.g., passivation protection layer) onto the passivation layer; or
(d) transfer to the second substrate processing module and deposit a passivation layer only (without depositing the second thin film).

In certain embodiments, there is an option for cooling along each of the stages.

In certain embodiments, the integrated substrate processing apparatus comprises a processing unit configured to cause the apparatus, under vacuum, to: perform a surface modification or a material removal process on a SiC surface of a substrate for cleaning the surface in the first substrate processing module; and depositing a SiO₂ layer, or a nanolaminate of SiO₂ and another oxide, onto the cleaned surface in the second substrate processing module.

In certain embodiments, the integrated substrate processing apparatus comprises a processing unit configured to cause the apparatus, under vacuum, to perform for substrate(s):
oxide or oxygen removal from a GaN substrate surface to clean the surface in the first substrate processing module; and
metal film deposition onto the cleaned surface in the second substrate processing module.

In certain embodiments, the metal film deposition comprises metal nitride film deposition.

In certain embodiments, the integrated substrate processing apparatus comprises a processing unit configured to cause the apparatus, under vacuum, to perform for substrate(s):
oxidizing remote plasma treatment or remote plasma deoxygenation treatment on carbon nano tube substrate(s) (or pellicle(s)) in the first substrate processing module for improving surface reactivity and/or to promote nucleation;

seed material layer, preferably Ru, deposition in the first or second substrate processing module (by thermal ALD); and
protective layer, preferably SiO₂, deposition onto the seed material layer in the second substrate processing module (by thermal ALD).

According to a second example aspect of the invention there is provided a method for processing substrates in an integrated substrate processing apparatus, comprising substrate modules integrated, under vacuum, via a wafer handling module, the method comprising:
processing one substrate at a time in a plasma-enhanced process in a first substrate processing module provided with a remote plasma generator, and
processing at least one substrate in a thermal mode for thin film deposition at a time in a second substrate processing module, said second substrate processing module comprising a heated substrate support.

In certain embodiments, the method comprises:
moving at least one substrate onto a substrate holder in said second substrate processing module;
lowering a reaction chamber lid (together with the substrate holder) and closing the reaction chamber;
operating thermal mode for thin film deposition;
raising the reaction chamber lid to an upper position;
removing said at least one substrate from the second substrate processing module.

In certain embodiments, the method further comprises:
aligning said at least one substrate in accordance with a predefined angular alignment;
cooling down said at least one substrate;
moving said at least one substrate into a load lock for removal.

In certain embodiments, prior to moving the at least one substrate onto the substrate holder, the at least one substrate (wafer) is loaded one at a time from a load lock (from a vacuum cassette elevator cassette) to an aligner. In the aligner, the at least one substrate is aligned in accordance with a predefined angular alignment in certain embodiments. In certain embodiments, the at least one substrate is transferred from the aligner via the wafer handling module to the first or second substrate processing module.

In certain embodiments, the method comprises:
performing a surface modification or a material removal process on a SiC surface of a substrate for cleaning the surface in the first substrate processing module; and depositing a SiO₂ layer, or a nanolaminate of SiO₂ and another oxide, onto the cleaned surface in the second substrate processing module.

In certain embodiments, the method comprises:
oxide or oxygen removal from a GaN substrate surface to clean the surface in the first substrate processing module; and
metal film deposition onto the cleaned surface in the second substrate processing module.

In certain embodiments, the method comprises:
oxidizing remote plasma treatment or remote plasma deoxygenation treatment on carbon nano tube substrate(s) (or pellicle(s)) in the first substrate processing module for improving surface reactivity and/or to promote nucleation;
seed material layer, preferably Ru, deposition in the first or second substrate processing module; and
protective layer, preferably SiO₂, deposition onto the seed material layer in the second substrate processing module.

According to a third example aspect there is provided an apparatus, comprising: at least one processor; and at least one memory including computer program code, the at least one memory and the computer program code being configured, with the at least one processor, to cause the apparatus to perform the method of the second example aspect or of any of its embodiments.

According to a fourth example aspect there is a computer program comprising computer executable program code which when executed by a processor causes an integrated substrate processing apparatus (such as the apparatus in accordance with the first example aspect or any of its embodiments) to perform the method of the second example aspect or of any of its embodiments.

Different non-binding example aspects and embodiments have been illustrated in the foregoing. The above embodiments are used merely to explain selected aspects or steps that may be utilized in implementations of the present invention. Some embodiments may have been presented only with reference to certain example aspect(s). It should be appreciated that corresponding embodiments apply to other example aspects as well. In particular, the embodiments described in the context of the first aspect are applicable to each further aspect, and vice versa. Any appropriate combinations of the embodiments may be formed.

### BRIEF DESCRIPTION OF THE DRAWINGS

The invention will now be described, by way of example only, with reference to the accompanying drawings, in which:

FIG. 1 shows an example layout of an integrated substrate processing apparatus in accordance with certain embodiments;

FIGS. 2-3 show certain examples of a second substrate processing module in accordance with certain embodiments;

FIGS. 4A-6E show certain examples of a first substrate processing module in accordance with certain embodiments;

FIG. 7 shows a block diagram of a control unit in accordance with certain embodiments; and

FIG. 8 shows a flow chart of a method in accordance with certain embodiments.

### DETAILED DESCRIPTION

In the following description, Atomic Layer Deposition (ALD) and Atomic Layer Etching (ALE) technologies are used as examples.

The basics of an ALD growth mechanism are known to a skilled person. ALD is a special chemical deposition method based on sequential introduction of at least two reactive precursor species to at least one substrate. A basic ALD deposition cycle consists of four sequential steps: pulse A, purge A, pulse B and purge B. Pulse A consists of a first precursor vapor and pulse B of another precursor vapor. Inactive gas and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness. Deposition cycles can also be either simpler or more complex. For example, the cycles can include three or more reactant vapor pulses separated by purging steps, or certain purge steps can be omitted. Or, as for plasma-assisted ALD, for example PEALD (plasma-enhanced atomic layer deposition), or for photon-assisted ALD, one or more of the deposition steps can be assisted by providing required additional energy for surface reactions through plasma or photon in-feed, respectively. Or one of the reactive precursors can be substituted by energy, leading to single precursor ALD processes. Accordingly, the pulse and purge sequence may be different depending on each particular case. The deposition cycles form a timed deposition sequence that is controlled by a logic unit or a microprocessor. Thin films grown by ALD are dense, pinhole free and have uniform thickness.

As for substrate processing steps, the at least one substrate is typically exposed to temporally separated precursor pulses in a reaction vessel (or chamber) to deposit material on the substrate surfaces by sequential self-limiting surface reactions. In the context of this application, the term ALD comprises all applicable ALD based techniques and any equivalent or closely related technologies, such as, for example the following ALD sub-types: MLD (Molecular Layer Deposition), plasma-assisted ALD, for example PEALD (Plasma Enhanced Atomic Layer Deposition) and photon-assisted or photon-enhanced Atomic Layer Deposition (known also as flash enhanced ALD or photo-ALD).

The basics of an ALE etching mechanism are known to a skilled person. ALE is a technique in which material layers are removed from a surface using sequential reaction steps that are self-limiting. A typical ALE etching cycle comprises a modification step to form a reactive layer, and a removal step to take off only the reactive layer. The removal step may comprise using a plasma species, ions in particular, for the layer removal. The source of plasma species can be varied, with a plasma applicator providing a source of plasma over a relatively large area being preferred. Plasma applicators may include a plasma array, a hollow cathode or microwave plasma, for example.

In the context of ALD and ALE techniques, the self-limiting surface reaction means that the surface reactions on the reactive layer of the surface will stop and self-terminate when the surface reactive sites are entirely depleted.

However, the invention is not limited to ALD and ALE technologies, but it can be exploited in a wide variety of substrate processing apparatuses, for example, in Chemical Vapor Deposition (CVD) reactors systems.

In the following description, like reference signs denote like elements or steps.

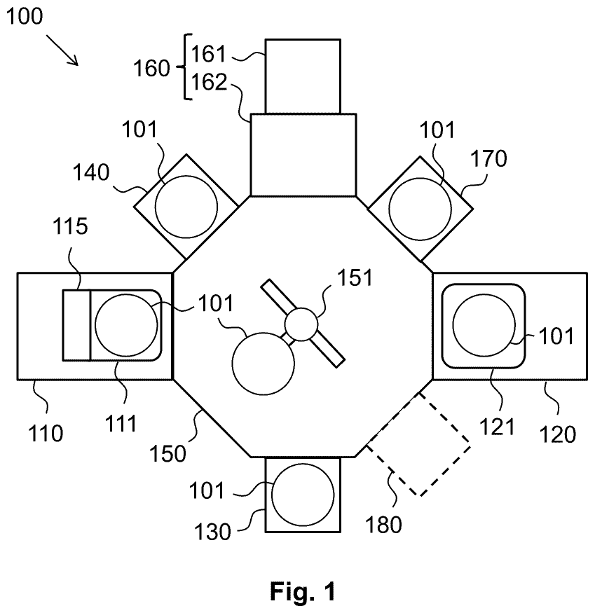

FIG. 1 shows an example layout of an integrated substrate processing apparatus 100 in accordance with certain embodiments. The apparatus 100 comprises substrate modules integrated, under vacuum, via a wafer (or substrate) handling module 150. The substrate modules comprise a first substrate processing module 110 provided with a remote plasma generator 115. The first substrate processing module 110 is configured to process one horizontally oriented substrate 101, such as a wafer, at a time in a plasma-enhanced process within a reaction chamber 111. In certain embodiments, the plasma-enhanced process is a self-limiting process, such as a process based on self-limiting surface reactions. In certain embodiments, the plasma-enhanced process is a deposition process, such as a thin film process. In certain embodiments, the plasma-enhanced process is a removal process, such as an etching process, e.g., an ALE process. In certain embodiments, the plasma-enhanced process is a modification process, such as a cleaning, doping, altering or smoothing process.

The substrate modules further comprises a second substrate processing module 120. The second substrate processing module 120 is capable of processing at least one substrate 101 at a time in a thermal mode for thin film deposition within a reaction chamber 121. In certain embodiments, the thermal mode for thin film deposition is an ALD process.

In certain embodiments, substrates 101 are received into the apparatus through a front-end module 160. In certain embodiments, the front-end module 160 comprises a pod opener 161 followed by a load lock 162. In certain embodiments, the load lock comprises a vacuum cassette elevator (VCE). In certain embodiments, a wafer handler (substrate handler) 151 of the wafer handling module 150 transfers substrates across or within the apparatus 100. Accordingly, in certain embodiments, the wafer handler 151 picks up one substrate 101 at a time from a VCE cassette (or load lock 162) and transfers the substrate 101 into the reaction chamber 111 of the first substrate processing module 110. The orientation of the substrate 101 is horizontal. The substrate surface is processed in a plasma-enhanced process within the reaction chamber 111. The direction of gas flows within the reaction chamber 111 is top-to-bottom. The wafer handler 151 then transfers the substrate 101 into the second substrate processing module 120. In certain embodiments, the substrate is not transferred directly into the second substrate processing module 120, but the substrate 101 is first transferred into a buffer module (pre-post processing module) 130 for waiting a subsequent transfer into the second substrate processing module 120. The orientation of the substrate is horizontal throughout the apparatus 100. The substrate 101 is loaded onto a substrate holder (not shown in FIG. 1) in the second substrate processing module 120 and lowered onto a substrate support (not shown in FIG. 1) in the reaction chamber 121. The horizontally oriented substrate 101 is then processed in a thermal mode for thin film deposition within the reaction chamber 121. The direction of gas flows within the reaction chamber 121 is top-to-bottom. Subsequent to the processing, the substrate 101 is elevated back into a loading position. The substrate 101 as horizontally oriented is then removed from the second substrate processing module 120 by the wafer handler 151.

In certain embodiments, the apparatus 100 comprises a cooling chamber 140. In certain embodiments, the substrate(s) 101 removed from the second substrate processing chamber 120 are transferred into the cooling chamber 140 for cooling.

In certain embodiments, the apparatus 100 comprises a substrate aligner module 170. In certain embodiments, the substrate(s) 101 removed from the second substrate processing chamber 120 are transferred into the substrate aligner module 170 for alignment, such as angular alignment.

In certain embodiments, the substrate(s) 101 are transferred into the substrate alignment module 170 for alignment, such as angular alignment, prior to their transfer into the first substrate processing module 110. Or there may be two substrate alignment modules, one for initial alignment and one for alignment subsequent to processing.

In certain embodiment, the apparatus 100 comprises a further optional chamber 180 for additional substrate processing as the case may be.

In certain embodiments, the substrate(s) 101 are removed from the apparatus 100 through the front-end module 160.

In certain embodiments, the apparatus 100 comprises substrate modules integrated, under vacuum, via the wafer handling module 150, wherein vacuum pressure is in the range extending from 100 mPa to 3 kPa.

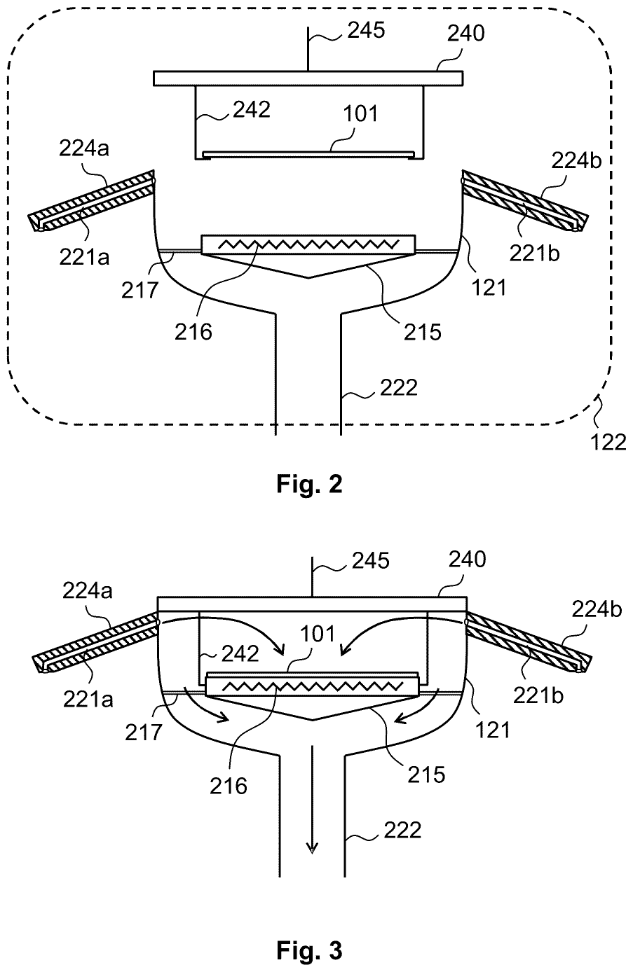

FIGS. 2 and 3 show certain embodiments of the second substrate processing module 120 in accordance with certain embodiments. FIG. 3 is a side view showing single substrate processing within the module 120, and FIG. 2 shows loading and unloading of substrates 101 to and from the module 120. The module 120 in certain embodiments comprises an outer (vacuum) chamber 122 at least partly accommodating the reaction chamber 121. The outer chamber 122 is provided with a loading section, such as a hatch, an opening, an openable lid, or similar (not shown). A reaction chamber lid 240 has been raised to an upper position (lid open position) with an elevator 245. In other embodiments, the reaction chamber lid 240 is part of a lid system comprising both a lid to the reaction chamber and a lid to the outer chamber (not shown). A substrate holder 242 is attached (integrated) to the lid 340. When loading, a horizontally oriented substrate 101 is transferred onto the substrate holder 242 through the loading section. The substrate holder 242 supports the substrate 101 with fingers or pins from below. The combination of the lid 240 and the substrate holder 242 is lowered by the elevator 245 into the reaction chamber 121. The substrate holder 242 lowers the substrate 101 onto a substrate support 215. The substrate holder 242 is subsequently moved further downwards so that the fingers or pins of the substrate holder 242 continue their downwards movement into recesses arranged in the substrate support 215.

In certain embodiments, the lid 240 in the substrate processing position (FIG. 3) closes the reaction chamber 121 (and the outer chamber 122 in the event of the lid system). The substrate 101 is processed within the reaction chamber 121 by a top-to-bottom flow of a reactive gaseous chemical (or chemicals as sequentially introduced) in a thermal mode of thin film deposition. In certain embodiments, the top-to-bottom flow is established by arranging a set of inlets parts (or inlets) 224a, 224b for the gaseous reactive chemical(s) above the horizontally oriented substrate 101. An outlet connection is arranged underneath the substrate 101 so that the general flow direction through the reaction chamber 121 is from top-to-bottom as shown in FIG. 3. In certain embodiments, respective chemical in-feed lines 221a, 221b within the inlet parts 224a, 224b have respective inlet openings in respective side walls of the reaction chamber 121. In certain embodiments, the reaction chamber 121 comprises an exhaust line or exhaust line connection 222 at the bottom of the reaction chamber 121.

In certain embodiments, the inlet parts 224a, 224b (in-feed lines 221a, 221b) are perpendicular to the respective side walls of the reaction chamber 121 (so that chemical is discharged into the reaction chamber 121 in a generally horizontal direction). In other embodiments, as shown in FIG. 3, the inlet parts 224a, 224b (in-feed lines 221a, 221b) have been arranged to meet the reaction chamber 121 in an inclined manner (at an inclined angle). An inclination upwards aids in lateral spreading of chemical(s) within the reaction chamber 121.

FIGS. 2 and 3 show two inlets for the gaseous reactive chemical(s), i.e., two precursor inlets. In certain embodiments, the module 120 comprises (or the reaction chamber 121 is provided with) at least 4, preferably 4 to 6, independent precursor inlets. In certain embodiments, each of the inlets is adjusted by its own respective pulsing valve (not shown) controlled by a control unit. In certain embodiments, the inlets are evenly positioned around reaction chamber periphery. In certain embodiments, the reaction chamber 121 is arranged as a bowl or comprises a bowl-like shape.

In certain embodiments, the substrate support 215 is stationary. In certain embodiments, the substrate support 215 is attached to the reaction chamber 121 wall by one or more fixing elements 217, such as rod(s). In certain embodiments, the substrate support 215 comprises a bottom part of the shape of an inverted cone to promote flow geometry.

The substrate support 215 is a heated substrate support. Accordingly, in certain embodiments, the substrate support 215 comprises a heater element 216.

When unloading, combination of the lid 240 and substrate holder 242 is raised into its upper position. The horizontally oriented substrate 101 is transferred from the substrate holder 242 and through the loading section out of the module 120 (by the wafer handler 151).

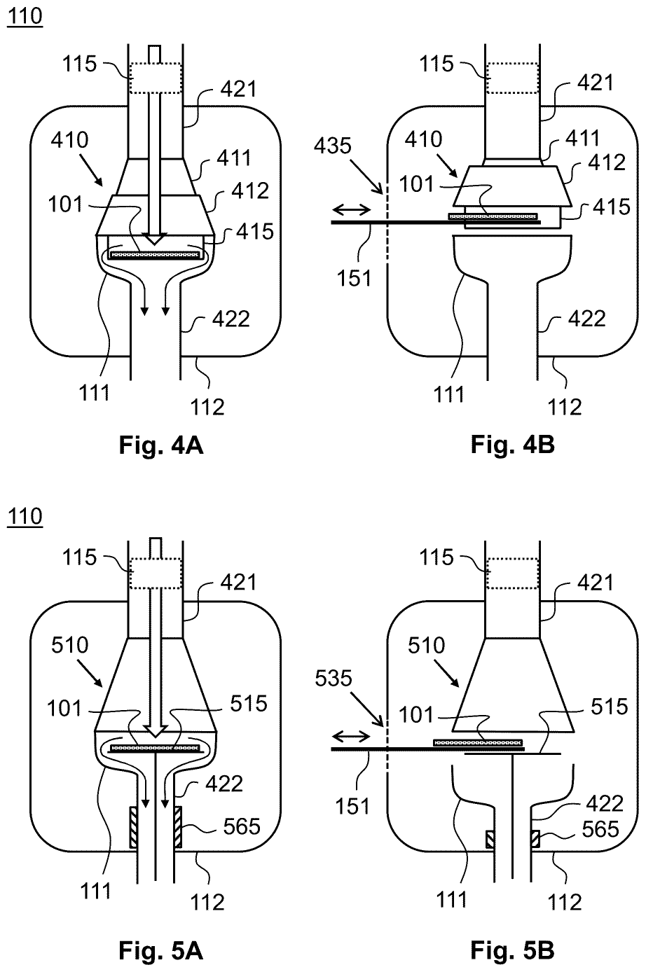

FIGS. 4A and 4B show certain examples of the first substrate processing module 110 in accordance with certain embodiments. FIG. 4A is a side view showing single substrate processing within the module 110, and FIG. 4B shows loading and unloading of substrates 101 to and from the module 110. The module 110 in certain embodiments comprises an outer (vacuum) chamber 112 at least partly accommodating the reaction chamber 111. The outer chamber 112 is provided with a loading section (such as a hatch, an opening, or similar) 435 shown by a dashed line. The module 110 comprises a plasma generator 115 (in an in-feed line 421) remotely positioned with respect to the substrate 101. Accordingly, the plasma generator 115 is a remote plasma generator 115, preferably a microwave remote plasma generator. During substrate processing as shown in FIG. 4A, plasma species generated by the remote plasma generator 115 enter the substrate processing volume (or reaction space) through an in-feed part 410 from the top of the reaction chamber 111. Exhaust of gases is arranged beneath the substrate 101 into an exhaust line 422 at the bottom of the reaction chamber 111.

A substrate holder 415 supporting a substrate 101 is attached to (or is suspended from) the in-feed part 410. When loading, a horizontally oriented substrate 101 is transferred to the substrate holder 415 through the loading section 435. When unloading, the horizontally oriented substrate 101 is transferred from the substrate holder 415 and through the loading section 435 out of the module 110. In certain embodiments, the substrate 101 is transferred by the wafer handler 151.

In certain embodiments, the in-feed part 410 comprises a retractable cone. In certain embodiments, the in-feed part 410 is formed of at least two nested conical parts 411, 412 forming a telescopic structure. During substrate loading, as shown in FIG. 4B, the retractable cone is in its retracted configuration with one of the nested parts (here: lower part or bottom part 412) slid over another (here: upper part or top part 411) thereby forming a loading gap for the substrate 101. During substrate processing, as shown in FIG. 4A, the retractable cone is in its extended configuration closing the reaction chamber 111 from the top.

The in-feed part 410 allows a top-to-bottom flow of plasma species towards the surface of the horizontally oriented substrate 101. Applicable gases for the generation of plasma species comprise Ar, NH₃, N₂ or H₂ or the like and any mixtures thereof.

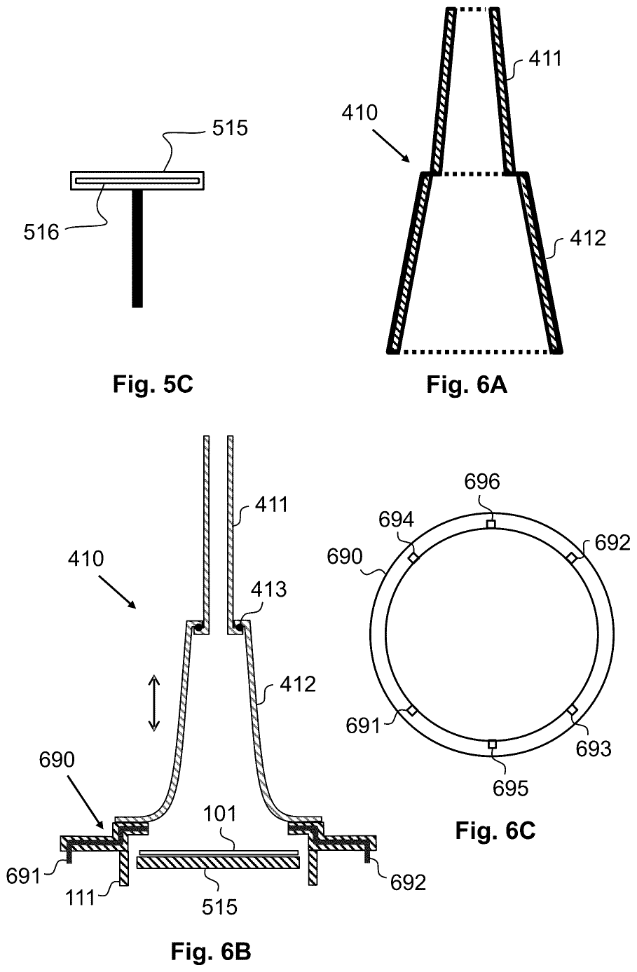

FIG. 5A is a side view showing single substrate processing within an alternative first substrate processing module 110, and FIG. 5B shows loading and unloading of substrates 101 to and from that module 110. The alternative first substrate processing module 110 in certain embodiments comprises an outer (vacuum) chamber 112 at least partly accommodating the reaction chamber 111. The outer chamber 112 is provided with a loading section (such as a hatch, an opening, or similar) 535 shown by a dashed line. The module 110 comprises a plasma generator 115 (in an in-feed line 421) remotely positioned with respect to the substrate 101. Accordingly, the plasma generator 115 is a remote plasma generator 115, preferably a microwave remote plasma generator. During substrate processing as shown in FIG. 5A, plasma species generated by the remote plasma generator 115 enter the substrate processing volume (or reaction space) through a conical in-feed part 510 (here: a stationary cone) from the top of the reaction chamber 111. Exhaust of gases is arranged beneath the substrate 101 into an exhaust line 422 at the bottom of the reaction chamber 111.

A substrate holder 515 supporting a substrate 101 within the reaction chamber 111 extends from the exhaust line 422 (or is supported through the exhaust line 422). In certain embodiments, the substrate holder 515 is stationary.

In certain embodiments, the exhaust line 422 comprises a deforming portion 565, such as a vacuum bellows, allowing a deformation of the exhaust line wall.

For substrate loading, a lower portion of the reaction chamber 111 (a reaction chamber bowl) is lowered to its lowered position to form a loading gap as shown in FIG. 5B. The deforming portion 565 is in its contracted configuration. A horizontally oriented substrate 101 is transferred to the substrate holder 515 through the loading section 535. When unloading, the horizontally oriented substrate 101 is transferred from the substrate holder 515 and through the loading section 535 out of the module 110. In certain embodiments, the substrate 101 is transferred by the wafer handler 151.

For substrate processing, as shown in FIG. 5A, the lower portion of the reaction chamber 111 is in its raised position. In certain embodiments, the lower portion of the reaction chamber 111 contacts the conical in-feed part 510 thus closing the reaction chamber 111 for substrate processing.

The conical in-feed part 510 allows a top-to-bottom flow of plasma species towards the surface of the horizontally oriented substrate 101.

In certain embodiments, the substrate holder 515 is a heated substrate holder. FIG. 5C shows such a heated substrate holder 515 comprising a heater element 516.

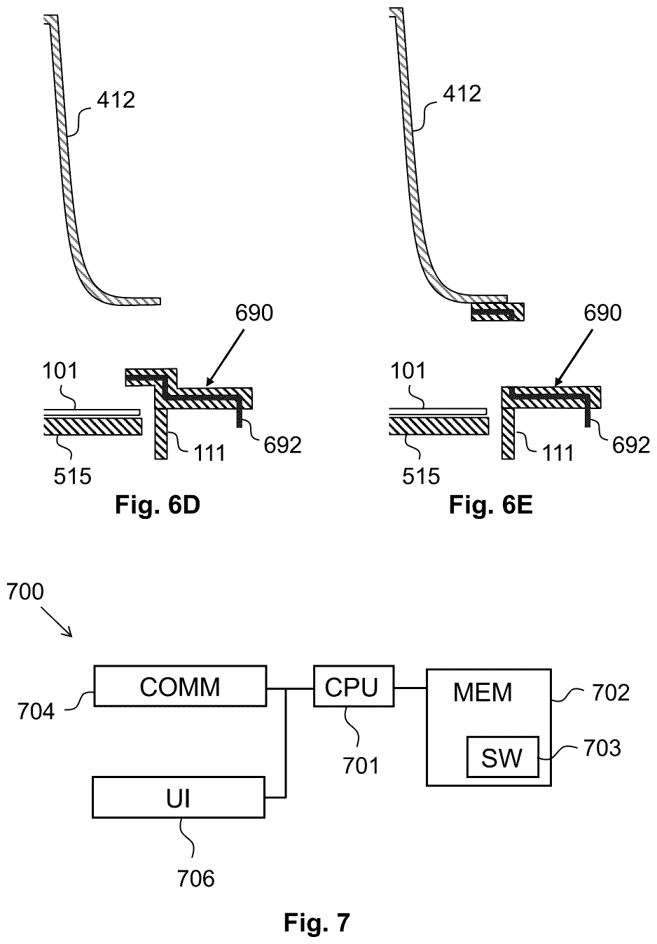

Generally, the in-feed part (referred to as in-feed part 410 or 510 in the preceding) may take on a variety of shapes in various embodiments. As shown in FIGS. 6A and 6B, the in-feed part may take the shape of a cone. For example the two piece cone of FIG. 6A comprising the top part 411 and bottom part 412. FIG. 6B shows an embodiment wherein the in-feed part comprises a trumpet like shape. As seen, the top part 411 may be in the shape of a straight walled (cylindrical) tube, interfacing at a seal 413 with a bottom part 412. The bottom part 412 of FIG. 6B comprises a tube exhibiting a curved wall, bell or trumpet shape in at least a lower portion of the bottom part.

FIG. 6B also shows the substrate 101 upon a, preferably stationary, substrate holder 515 (although in other embodiments, the substrate holder may be integrated to (or suspended from) the bottom part 412 for combined movement with the bottom part 412) and (oppositely arranged) in-feed paths 691 and 692 for non-plasma precursor(s). For the sake of illustration, the in-feed paths do not show inlets or nozzles and instead show a combined path. The reference numeral 690 illustrates a reaction chamber bowl top part, such as a reaction chamber bowl upper flange or similar.

FIG. 6C shows a top view illustrating various inlet locations for non-plasma precursor in-feed into the reaction chamber 111, arranged in the reaction chamber bowl top part 690. In addition to inlets at end points of in-feed paths 691 and 692, FIG. 6C shows 4 further inlets at end points of respective in-feed paths 693-696. The inlets are distributed in a circular fashion (at a peripheral edge area of the reaction chamber 111 above the substrate holder 515).

FIGS. 6D and 6E show different arrangements with regard to the inlets. In the alternative shown in FIG. 6D, the in-feed paths (in-feed path 692 is shown) are implemented completely within the reaction chamber bowl top part 690. In the alternative shown in FIG. 6E, the in-feed paths enter from the reaction chamber bowl top part 690 to the bottom part 412 of the in-feed part 410 through respective interfaces. Accordingly, when a loading gap is being formed by sliding the bottom part 412 over the top part 411 (not shown in FIGS. 6D and 6E), the in-feed part remains within the reaction chamber top part 690 in the arrangement shown in FIG. 6D. In the arrangement shown in FIG. 6E, to the contrary, the in-feed path 692 is disconnected so that a first portion of the in-feed path 692 remains within the reaction chamber top part 690 and a second portion of the in-feed path 692 remains fixed to the bottom part 412 (when the bottom part 412 is moved away from part 690, or raised, to form a loading gap).

FIG. 7 shows a block diagram of a control unit 700 in accordance with certain example embodiments. The control unit 700 comprises at least one processor 701 configured to control the operation of the apparatus 100 and at least one memory 702 comprising a computer program or software 703. The software 703 includes instructions or a program code to be executed by the at least one processor 701 to control the apparatus 100. The software 703 may typically comprise an operating system and different applications. In certain embodiments, the control unit 700 is configured as a computerized system, which uses one or more computers.

The at least one memory 702 may form part of the apparatus 100 or it may be formed of an attachable module. The control unit 700 further comprises at least one communication unit 704. The communication unit 704 provides for an interface for internal communication of the apparatus 100. In certain embodiments, the control unit 700 uses the communication unit 704 to send instructions or commands to valves, heater(s), pressure sensor(s), vacuum pump(s), and other adjustment devices (not shown). In certain embodiments, the control unit 700 uses the communication unit 704 further to receive data from different parts of the apparatus 100, such as from different sensors etc.

The control unit 700 may further comprise a user interface 706 to co-operate with an operator, for example, to receive input such as process parameters from the operator. In certain embodiments, the user interface 706 is connected to the at least one processor 701.

In certain embodiments, the control unit 700, inter alia, is programmed (i.e., the control unit 700 or processor 701 is configured, based on the stored instructions in memory) to cause the apparatus 100 to process one substrate 101 at a time in a plasma-enhanced process in the first substrate processing module 110, and at least one substrate 101 at a time in a thermal mode for thin film deposition in the second substrate processing module 120. Further control of the apparatus 100 that the control unit 700 is programmed to control in certain embodiments comprises control of opening and closing times of pulsing valves, control of substrate transfer with the wafer handler 151, control of optional buffering times within the buffer module 130, if implemented, etc.

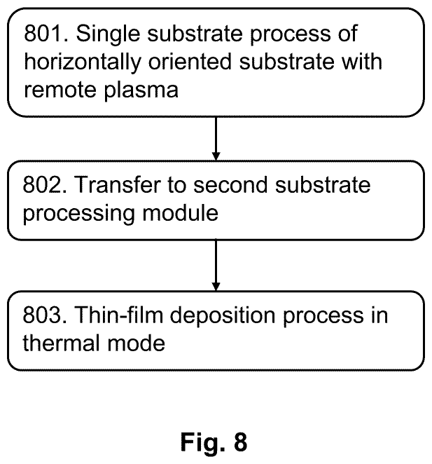

FIG. 8 shows a flow diagram of a method in accordance with certain embodiments. In step 801, a horizontally oriented substrate 101 is processed by a single substrate process with remote plasma (in the first substrate processing module 110). In certain embodiments, the single substrate process is a plasma-enhanced ALE or plasma-enhanced ALD process, or a plasma-enhanced surface modification process. In step 802, the substrate 101 is transferred (under vacuum) to the second substrate processing module 120. In step 803, the substrate 101 is processed in thermal mode for thin film deposition. In certain embodiments, the process within the second substrate processing module is an ALD process.

In certain embodiments, the method comprises plasma treatment (surface pre-treatment) of a substrate 101 within the first substrate processing module 110 and ALD thin film deposition on the substrate 101 within the second substrate processing module 120.

In certain embodiments, the method comprises plasma treatment (surface pre-treatment) of a substrate 101 within the first substrate processing module 110, PEALD or ALD thin film deposition on the substrate 101 within the first substrate processing module 110, and ALD thin film deposition within the second substrate processing module 120.

### EXAMPLES

Certain examples are described in the following to illustrate the described embodiments.

In a first example, a cleaning step and an ALD step are performed for gate oxide deposition to improve mobility and/or to reduce power consumption in SiC devices. A substrate (or wafer) 101 having a SIC surface is first transferred via the wafer handling module 150 into the first substrate processing module 110 for single substrate processing. The SiC surface is exposed to a plasma-enhanced process in which remote plasma is used to clean the SIC surface. Surface defect reduction is obtained by carbon removal through the use of plasma. Remote plasma is used to prevent degradation of the SiC crystalline structure and diffusion of hydrogen into the bulk of the material. The substrate 101 is then transferred into the second substrate processing module 120. A passivation layer of e.g. 50-70 nm of SiO₂, gate oxide, is deposited by an ALD step onto the cleaned substrate surface. In a modified example, instead of mere SiO₂ deposition, a nanolaminate of SiO₂/HfO₂ or SiO₂/Al₂O₃ is deposited by the ALD step to improve substrate electrical characteristics. Once both the first substrate processing module 110 and the second substrate processing module 120 are connected to the same wafer handling module 150 (wafer handler 151) under vacuum, atmospheric contamination mainly due to oxidation and carbon input is avoided. Further, performing both steps in the same system, without vacuum break, allows an excellent control of the surface properties.

In a second example, a surface of a substrate is passivated for a GaN device. A substrate (or wafer) 101 having a GaN surface is first transferred via the wafer handling module 150 into the first substrate processing module 110 for single substrate processing. The GaN surface is exposed to a plasma-enhanced process in which remote plasma is used to clean the GaN surface. Surface defect reduction is obtained by surface deoxygenation or deoxidation through the use of plasma. Remote plasma is used to prevent degradation of the GaN crystalline structure and diffusion of hydrogen into the bulk of the material. Oxygen or oxide removal reduces the resistivity of the GaN device as desired. Subsequently, the GaN surface is passivated within the first substrate processing module 110 with a metal nitride layer, such as AlN herein. The nitride layer is deposited by plasma-enhanced ALD using remote plasma generation. The substrate 101 is then transferred into the second substrate processing module 120 for deposition of a passivation protection layer. A capping layer of Al₂O₃, serving as passivation protection in this example, is deposited by an ALD step onto the passivation layer. Once both the substrate processing module 110 and the second substrate processing module 120 are connected to the same wafer handling module 150 (wafer handler 151) under vacuum, atmospheric contamination is avoided. Further, performing all steps in the same system, without vacuum break, allows an excellent control of the surface properties.

In a third example, a carbon nano tube substrate or a carbon nano tube pellicle is coated with a seed material layer and a protective layer. A substrate 101 formed of carbon nano tubes (or a carbon nano tube pellicle) is first transferred via the wafer (or substrate) handling module 150 into the first substrate processing module 110.

The carbon nano tube surface is exposed to a plasma-enhanced process in which remote plasma is used to oxidize the surface. As an example, a pulse of H₂O with, preferably microwave, remote plasma generator 112 with Ar plasma activated is used to create in-situ reactive O-species that react with the carbon nano tube surface to promote functionalization for an ALD seed material layer, preferably Ru, with minimal damage on the carbon nano tube surface and to promote nucleation. Subsequently, the substrate 101 is transferred into the second substrate processing module 120. The seed material layer, preferably Ru, is deposited onto the plasma treated (oxidized) carbon nano tube surface in the second substrate processing module 120 as an ALD thin film process. Yet further, a protective layer, preferably SiO₂, is deposited onto the seed material layer in the second substrate processing module 120 as an ALD thin film process.

Without limiting the scope and interpretation of the patent claims, certain technical effects of one or more of the example embodiments disclosed herein are listed in the following. A technical effect is providing single substrate plasma treatment of a horizontally oriented substrate and thin film deposition of the horizontally oriented substrate within the same cluster apparatus (without any vacuum break). A further technical effect is surface treatment without degradation of material structure of an underlying surface material layer in a plasma-enhanced process in an integrated substrate processing apparatus (cluster). A further technical effect is prevention of diffusion of hydrogen into the bulk of the underlying material layer. A further technical effect is avoidance of atmospheric contamination. A further technical effect is prevention of ion bombardment on a substrate surface through the use of a remote plasma generator apparatus. A plasma applicator where plasma is generated is positioned far from the substrate to prevent ion bombardment (but allowing plasma radicals to reach the substrate surface). A yet further technical effect is allowing plasma delivery without favoring recombination of plasma species by implementing a top-to-bottom flow and/or by arranging a flow path from the remote plasma generator (or applicator) to the substrate without any obstacles in the flow path (like a showerhead). A technical effect is promoting a high level of radicals but a low level or no ions to reach the substrate surface due to the use of remote plasma and in certain embodiments also due to arranging an in-feed part directing plasma from the remote plasma generator to the substrate without having any obstacles in a flow part formed. It has been observed that radicals driven chemical reactions are preferable over ion bombardment driven physical reactions. A technical effect gained from using, in the first substrate processing module (for plasma-enhanced process), a cylindrical tube followed by a trumpet-shaped part, where the trumpet-part is slidable over the cylindrical tube, is an increased gas velocity resulting in lower purge times (reduced cycle times), and a reduced chamber volume and surface area resulting in reduced radical (or plasma species) recombination.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1. An integrated substrate processing apparatus, comprising substrate modules integrated, under vacuum, via a wafer handling module, wherein the substrate modules comprise:
a first substrate processing module provided with a remote plasma generator, configured to process one substrate at a time in a plasma-enhanced process, and
a second substrate processing module capable of processing at least one substrate in a thermal mode for thin film deposition, said second substrate processing module comprising a heated substrate support.

2. The integrated substrate processing apparatus of claim 1, wherein the first substrate processing module comprises an in-feed part to deliver a generated flow of plasma species from the remote plasma generator to the substrate.

3. The integrated substrate processing apparatus of claim 2, wherein first substrate processing module comprises a conical in-feed part for a top-to-bottom flow of plasma species.

4. The integrated substrate processing apparatus of claim 3, wherein the conical in-feed part comprises a retractable cone.

5. The integrated substrate processing apparatus of claim 2, wherein the in-feed part comprises first a cylindrical or conical part followed by a trumpet-shaped part.

6. The integrated substrate processing apparatus of claim 1, wherein the first substrate processing module is configured to provide gas activated or excited through the remote plasma generator, and targeted to the single substrate surface for a thin film deposition, a surface modification, or material removal process, wherein the material removal process comprises oxidation or deoxidation or deoxygenation, and/or decarbonation, and/or nitridation.

7. (canceled)

8. The integrated substrate processing apparatus of claim 1, wherein the first substrate processing module comprises a substrate holder comprising a heater element.

9. The integrated substrate processing apparatus of claim 1, wherein at least one of the following elements are stationary:
a substrate holder of the first substrate processing module;
the heated substrate support of the second substrate processing module.

10. (canceled)

11. The integrated substrate processing apparatus of claim 1, wherein the second substrate processing module is configured to provide a top-to-bottom flow of a precursor towards a horizontally oriented substrate.

12. (canceled)

13. The integrated substrate processing apparatus of claim 1, wherein the first and/or second processing module comprises at least 4, preferably 4 to 6, independent precursor inlets.

14. The integrated substrate processing apparatus of claim 1, configured to passivate the substrate(s) in substrate modules by depositing a first thin film and then depositing a second thin film onto the first thin film, or by first performing surface modification and then depositing a thin film onto the modified surface.

15. (canceled)

16. (canceled)

17. The integrated substrate processing apparatus of claim 1, comprising a processing unit configured to cause the apparatus, under vacuum, to perform for substrate(s):
(a) substrate surface modification or material removal process in the first substrate processing module;
(b) optionally transfer to a pre-post processing module via the wafer handling module; and
(c) transfer to the second substrate processing module and deposit a passivation layer and a second thin film onto the passivation layer; or
(d) transfer to the second substrate processing module and deposit a passivation layer only.

18. The integrated substrate processing apparatus of claim 1, comprising a processing unit configured to cause the apparatus, under vacuum, to:
perform a surface modification or a material removal process on a SiC surface of a substrate for cleaning the surface in the first substrate processing module; and
depositing a SiO₂ layer, or a nanolaminate of SiO₂ and another oxide, onto the cleaned surface in the second substrate processing module.

19. The integrated substrate processing apparatus of claim 1, comprising a processing unit configured to cause the apparatus, under vacuum, to perform for substrate(s):
oxide or oxygen removal from a GaN substrate surface to clean the surface in the first substrate processing module; and
metal film deposition onto the cleaned surface in the second substrate processing module.

20. The integrated substrate processing apparatus of claim 1, comprising a processing unit configured to cause the apparatus, under vacuum, to perform for substrate(s):
oxidizing remote plasma treatment or remote plasma deoxygenation treatment on carbon nano tube substrate(s) in the first substrate processing module for improving surface reactivity and/or to promote nucleation;
seed material layer, preferably Ru, deposition in the first or second substrate processing module; and
protective layer, preferably SiO2, deposition onto the seed material layer in the second substrate processing module.

21. A method for processing substrates in an integrated substrate processing apparatus, comprising substrate modules integrated, under vacuum, via a wafer handling module, the method comprising:
processing one substrate at a time in a plasma-enhanced process in a first substrate processing module provided with a remote plasma generator, and
processing at least one substrate in a thermal mode for thin film deposition in a second substrate processing module, said second substrate processing module comprising a heated substrate support.

22. The method of claim 21, comprising:
moving at least one substrate onto a substrate holder in said second substrate processing module;
lowering a reaction chamber lid and closing the reaction chamber;
operating thermal mode for thin film deposition;
raising the reaction chamber lid to an upper position;
removing said at least one substrate from the second substrate processing module;
aligning said at least one substrate in accordance with a predefined angular alignment;
cooling down said at least one substrate;
moving said at least one substrate into a load lock for removal.

23. (canceled)

24. The method of claim 21, comprising:
performing a surface modification or a material removal process on a SiC surface of a substrate for cleaning the surface in the first substrate processing module; and
depositing a SiO₂ layer, or a nanolaminate of SiO₂ and another oxide, onto the cleaned surface in the second substrate processing module.

25. The method of claim 21, comprising:
oxide or oxygen removal from a GaN substrate surface to clean the surface in the first substrate processing module; and
metal film deposition onto the cleaned surface in the second substrate processing module.

26. The method of claim 21, comprising:
oxidizing remote plasma treatment or remote plasma deoxygenation treatment on carbon nano tube substrate(s) in the first substrate processing module for improving surface reactivity and/or to promote nucleation;
seed material layer, preferably Ru, deposition in the first or second substrate processing module; and
protective layer, preferably SiO₂, deposition onto the seed material layer in the second substrate processing module.
